(19) United States
(12) Patent Application Publication
(10) Pub. No.: US 2021/0378105 A1
(43) Pub. Date: Dec. 2, 2021

(54) CIRCUIT BOARD AND METHOD FOR MANUFACTURING CIRCUIT BOARD

(71) Applicants: AutoNetworks Technologies, Ltd., Yokkaichi-shi, Mie (JP); Sumitomo Wiring Systems, Ltd., Yokkaichi-shi, Mie (JP); Sumitomo Electric Industries, Ltd., Osaka-shi, Osaka (JP)

(72) Inventor: Akira Haraguchi, Yokkaichi-shi, Mie (JP)

(21) Appl. No.: 16/767,654

(22) PCT Filed: Nov. 7, 2018
(86) PCT No.: PCT/JP2018/041316

§ 371 Date: May 28, 2020

(30) Foreign Application Priority Data
Nov. 28, 2017 (JP) 2017-228222

(51) Int. Cl. H05K 3/30; H05K 1/18; H05K 3/00; H05K 3/22

(52) U.S. Cl. CPC H05K 3/305; H05K 1/181; H05K 3/0014; H05K 1/0333; H05K 2201/0154; H05K 2201/10053; H05K 2201/10507; H05K 3/22

(57) ABSTRACT

A circuit board includes a conductive plate held by a holding member, an insulation sheet provided on one side of the conductive plate, and a circuit component that is placed on the conductive plate and that has a terminal, and a void portion is formed in the insulation sheet, and a conductive material for electrically connecting the conductive plate and the terminal to each other is applied to a region that is exposed from the void portion on the one side of the conductive plate.

### CROSS-REFERENCE TO RELATED APPLICATIONS

This application is the U.S. national stage of PCT/JP2018/041316 filed on Nov. 7, 2018, which claims priority of Japanese Patent Application No. JP 2017-228222 filed on Nov. 28, 2017, the contents of which are incorporated herein.

### TECHNICAL FIELD

The present invention relates to a circuit board and a method for manufacturing a circuit board.

### BACKGROUND

A circuit board is known which includes a plurality of conductive plates (metal plates) provided on one side of the board, and a circuit component whose terminals (electrodes) are respectively connected to the conductive plates (see JP 2015-115359A, for example).

A loop-shaped groove is provided in a surface of each conductive plate disclosed in JP 2015-115359A. A region surrounded by the groove includes a region on which the terminal of the circuit component can be placed, and due to a solder applied to that region, the terminal of the circuit component and the conductive plate are electrically connected to each other. Since this region is surrounded by the loop-shaped groove, when the solder is placed on this region, the solder that is likely to be pushed out is collected within the groove.

A configuration in which grooves are provided in a surface of a conductive plate requires the grooves to be wide enough to hold a solder, and a predetermined width (clearance) that is required for processing needs to be provided between any two grooves. Accordingly, it is difficult to densely arrange circuit components, and thus there is a problem in that an area for mounting the circuit components increases.

An object of this disclosure is to provide a circuit board and the like that can reliably and electrically connect a conductive plate and a circuit component to each other with a simple configuration.

### SUMMARY

A circuit board according to one aspect of the present disclosure includes a conductive plate held by a holding member, an insulation sheet provided on one side of the conductive plate, and a circuit component that is placed on the conductive plate and that has a terminal, and a void portion is formed in the insulation sheet, and a conductive material for electrically connecting the conductive plate and the terminal to each other is applied to a region that is exposed from the void portion on the one side of the conductive plate.

A method for manufacturing a circuit board according to one aspect of the present disclosure includes steps of arranging a plurality of conductive plates at a predetermined position in a mold and forming a holding member by pouring resin into the mold, while forming the plurality of conductive plates and the holding member in one piece, adhering an insulation sheet, on which a void portion is formed and that has a pressure-sensitive adhesive or adhesive layer on both sides and a protection paper adhered to one side thereof, to one side of the conductive plates, with a side on which the protection paper is not adhered facing the conductive plates, applying a conductive material to a region of the conductive plate where the void portion is located, removing the protection paper from the insulation sheet, and aligning a terminal of a circuit component with the void portion, placing the terminal on the conductive plate to which the conductive material is applied, and adhering or gluing the circuit component to the insulation sheet to fix the circuit component to the conductive plate.

### Advantageous Effects of Disclosure

According to this disclosure, it is possible to provide a circuit board and the like that can reliably and electrically connect a conductive plate and a circuit component to each other with a simple configuration.

### BRIEF DESCRIPTION OF DRAWINGS

FIG. 1 is a perspective view of a circuit board according to a first embodiment.

FIG. 2A is a diagram illustrating a configuration of bus bars.

FIG. 2B is a diagram illustrating a configuration of the bus bars.

FIG. 2C is a diagram illustrating a configuration of the bus bars.

FIG. 3 is a perspective view showing how the bus bars and a holding member are formed in one piece.

FIG. 4 is a perspective view of an insulation sheet.

FIG. 5 is a schematic cross-sectional view of a main part of the circuit board.

FIG. 6A is a diagram illustrating a method for manufacturing the circuit board.

FIG. 6B is a diagram illustrating the method for manufacturing the circuit board.

FIG. 6C is a diagram illustrating the method for manufacturing the circuit board.

FIG. 6D is a diagram illustrating the method for manufacturing the circuit board.

FIG. 6E is a diagram illustrating the method for manufacturing the circuit board.

FIG. 6F is a diagram illustrating the method for manufacturing the circuit board.

### DETAILED DESCRIPTION OF PREFERRED EMBODIMENTS

First, aspects of this disclosure will be listed and illustrated. At least some of the embodiments described below may also be combined as appropriate.

A circuit board according to one aspect of the disclosure includes a conductive plate held by a holding member, an insulation sheet provided on one side of the conductive plate, and a circuit component that is placed on the conductive plate and that has a terminal, and wherein a void portion is formed in the insulation sheet, and a conductive material for electrically connecting the conductive plate and the terminal to each other is applied to a region that is exposed from the void portion on the one side of the conductive plate.

In this aspect, by the conductive material for connecting the terminal and the conductive plate being applied to the region of the conductive plate that is exposed due to the void portion of the insulation sheet being located, it is possible, by using a thickness of the insulation sheet, to suppress the conductive material from flowing out from the void portion to the surrounding area.

A configuration is preferable in which the insulation sheet has a pressure-sensitive adhesive or adhesive layer on both sides thereof, and the circuit component is fixed to the conductive plate by the pressure-sensitive adhesive or adhesive layer.

In this aspect, by the circuit component being fixed to the conductive plate by the pressure-sensitive adhesive or adhesive layer of the insulation sheet, it is possible to suppress a phenomenon in which the circuit component rises up when the circuit board is introduced into the reflow furnace, and thus the manufacturability can be improved.

A configuration is preferable in which the pressure-sensitive adhesive layer is formed of an acrylic pressure-sensitive adhesive.

In this aspect, the pressure-sensitive adhesive layer formed by an acrylic pressure-sensitive adhesive makes it possible to improve the heat-resistance of the circuit board.

A configuration is preferable in which the base material of the insulation sheet is made of polyimide or cellulose.

In this aspect, the base material of the insulation sheet made of polyimide or cellulose makes it possible to improve the heat resistance of the circuit board.

A configuration is preferable in which the holding member is made of polyphenylene sulfide resin.

In this aspect, the holding member made of polyphenylene sulfide resin makes it possible to improve the heat resistance of the circuit board.

A configuration is preferable in which the circuit component includes a semiconductor switch, and a chip component that is smaller than the semiconductor switch, and the void portions are respectively formed corresponding to the terminals of the semiconductor switch and the chip component.

In this aspect, since the void portions of the insulation sheet are respectively formed corresponding to the terminals of the semiconductor switches and the terminals (electrodes) of the chip components that are smaller than the semiconductor switches, it is possible to easily configure the circuit board on which the circuit components of different sizes are mounted.

A method of manufacturing the circuit board according one aspect of the disclosure includes steps of arranging a plurality of conductive plates at a predetermined position in a mold and forming a holding member by pouring resin into the mold, while forming the plurality of conductive plates and the holding member in one piece, adhering an insulation sheet, on which a void portion is formed and that has a pressure-sensitive adhesive or adhesive layer on both sides and a protection paper adhered to one side thereof, to one side of the conductive plates, with a side on which the protection paper is not adhered facing the conductive plates, applying a conductive material to a region of the conductive plate where the void portion is located, removing the protection paper from the insulation sheet, and aligning a terminal of a circuit component with the void portion, placing the terminal on the conductive plate to which the conductive material is applied, and adhering or gluing the circuit component to the insulation sheet to fix the circuit component to the conductive plate.

In this aspect, it is possible to manufacture the circuit board according to the aspect of the disclosure with a simple manufacturing method, in which the void portion is formed, and the conductive material is applied to the region of the conductive plates on which the void portion is located with use of the insulation sheet having the pressure-sensitive adhesive or adhesive layer on both sides.

Specific examples of a circuit board and a method for manufacturing the circuit board according to the aspects of this disclosure will be described with reference to the drawings below. Note that the present invention is not limited to these examples, and is defined by the claims, and all changes within the meaning and range of equivalency of the claims are intended to be embraced therein.

### First Embodiment

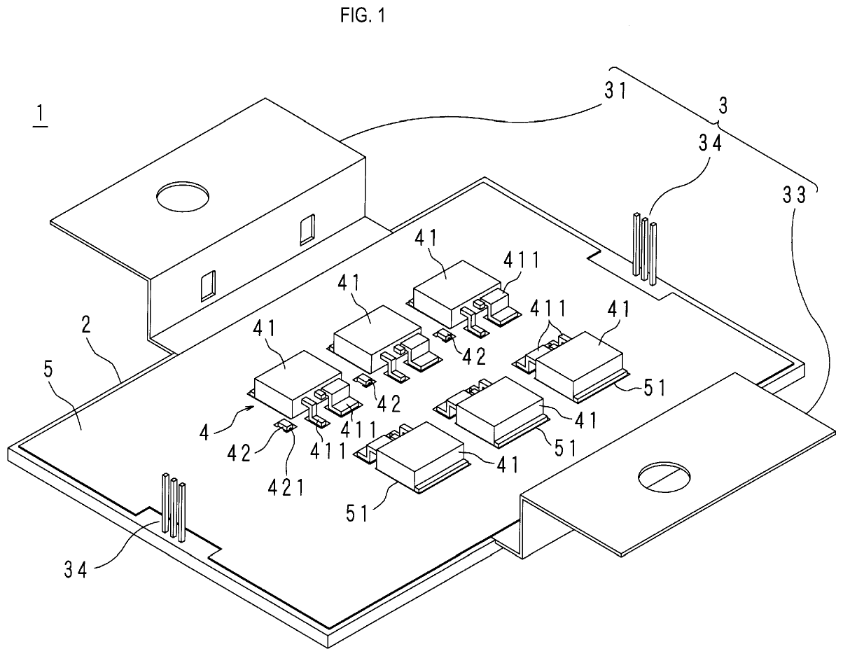

FIG. 1 is a perspective view showing a circuit board 1 according to a first embodiment. A circuit board 1 is provided with a holding member 2 and a plurality of bus bars 3 held by the holding member 2. An insulation sheet 5 having a plurality of void portions 51 is provided on one side of the bus bars 3. The circuit board 1 is provided with semiconductor switches 41 and chip components 42 as circuit components 4. The circuit board 1 is mounted in an electrical junction box (not shown), for example, and used as a power supply device for a vehicle.

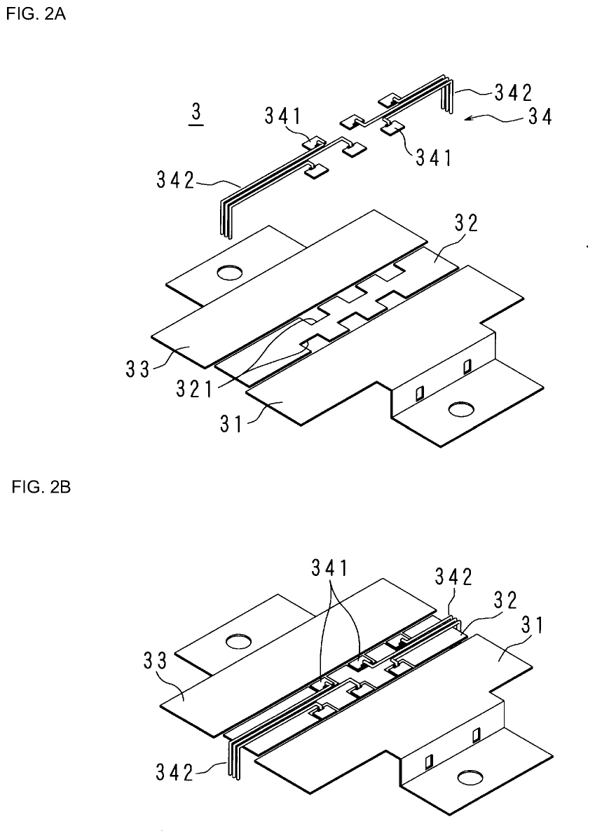

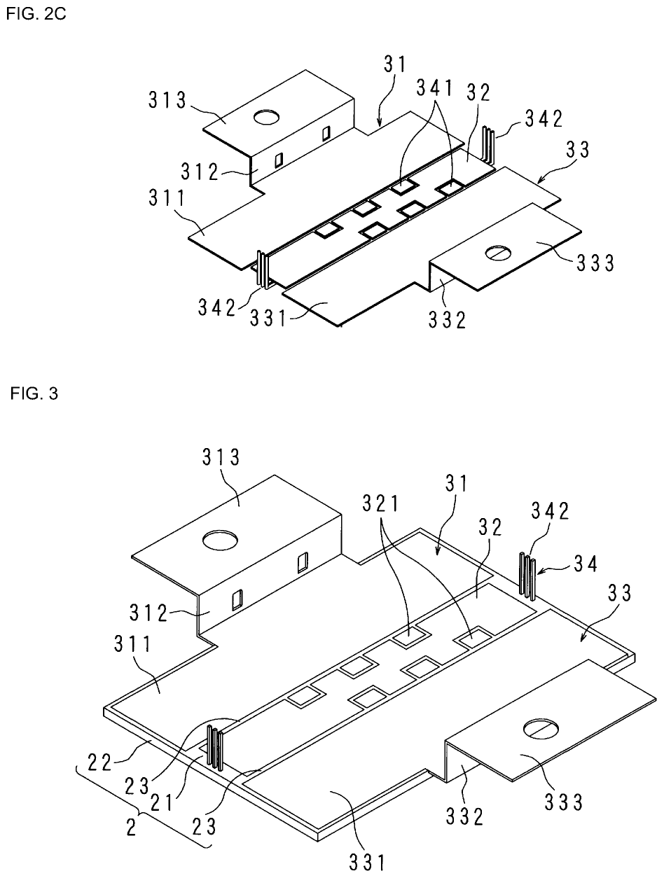

FIGS. 2A, 2B and 2C are diagrams illustrating a configuration of the bus bars. FIG. 3 is a perspective view showing how the bus bars and the holding member are formed in one piece. The bus bars 3 include an input bus bar 31, a connection bus bar 32, an output bus bar 33, and terminal bus bars 34. The bus bars 3 are made of a highly conductive metal such as copper, for example.

The input bus bar 31 and the output bus bar 33 respectively include placement portions 311 and 331 shaped like rectangular plates, on which the circuit components 4 are placed, rising portions 312 and 332 that rise substantially upright from outer edges of the placement portions 311 and 331, and extending portions 313 and 333 that extend outward from the top edges of the rising portions 312 and 332. The input bus bar 31 and the output bus bar 33 are held by the holding member 2 with the placement portions 311 and 331 thereof arranged in parallel with each other.

The rectangular plate-like connection bus bar 32 is provided between the placement portion 311 of the input bus bar 31 and the placement portion 331 of the output bus bar 33. The longitudinal edges of the connection bus bar 32 each have three cutout portions 321. The cutout portions 321 that face the input bus bar 31 and the output bus bar 33 are provided in the longitudinal edges of the connection bus bar 32. The input bus bar 31, the connection bus bar 32, and the output bus bar 33 are arranged in this order and in parallel with each other, and held by the holding member 2 with the side of the bus bars on which the circuit components 4 are placed facing in the same direction.

The terminal bus bars 34 include rectangular plate-like terminal placement portions 341, and rod portions 342 each extending from one edge of each terminal placement portion 341 (see FIG. 2A). The number of terminal bus bars 34 is six, which corresponds to the number of the cutout portions 321 provided in the connection bus bar 32. The terminal bus bars 34 are provided so that the terminal placement portions 341 are aligned with the cutout portions 321 provided in the connection bus bar 32 from the other side of the connection bus bar 32 (see FIGS. 2B and 2C). The front end portions of the rod portions 342 of the terminal bus bars 34 are bent so that they are substantially vertical to the one side of the connection bus bar 32.

The holding member 2 has a base portion 21 shaped like a rectangular plate. A protruding portion 22 shaped like a rectangular frame in a plan view is provided at the circumferential edge of one side of the base portion 21. Two protruding ridges 23 are provided substantially in parallel with each other and with a gap therebetween in the middle portion of the one side of the base portion 21, and the two ends of the protruding ridges 23 are connected to the inner circumferential face of the rectangular frame-like protruding portion 22. Accordingly, the holding member 2 has three regions partitioned by the rectangular frame-like protruding portion 22 and the two protruding ridges 23. The holding member 2 is made of a heat-resistant insulating resin, such as, preferably, polyphenylene sulfide resin, for example.

As shown in FIG. 3, the input bus bar 31 is provided between one long side of the rectangular frame-like protruding portion 22 and one protruding ridge 23. The output bus bar 33 is provided between another long side of the rectangular frame-like protruding portion 22 and another protruding ridge 23. A connection bus bar 32 is provided between the two protruding ridges 23. The rectangular frame-like protruding portion 22 of the holding member 2 covers the outer circumference of the bus bars 3 formed by the input bus bar 31, the connection bus bar 32, the output bus bar 33, and the terminal bus bars 34. The input bus bar 31, the connection bus bar 32, the output bus bar 33, and the terminal bus bars 34 are held by and fixed to the holding member 2, and form a mounting surface of the circuit board 1 with that side thereof on which the circuit components 4 are placed facing in the same direction. Note that the holding member 2 is not limited to having a base portion 21, and a protruding portion 22 and protruding ridges 23 that are formed on the base portion 21, and the holding member 2 may also be a frame having an outer frame and a columnar portion that bridges the inner side of the outer frame. In this case, the outer frame of the frame corresponds to the rectangular frame-like protruding portions 22, and the columnar portion corresponds to the protruding ridges 23.

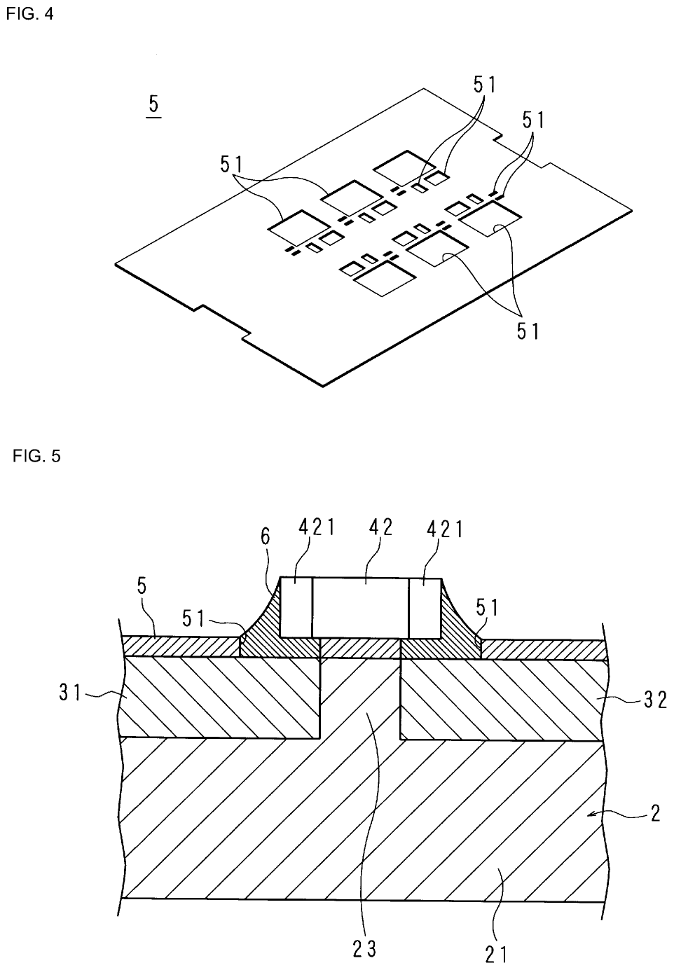

FIG. 4 is a perspective view of an insulation sheet 5. The insulation sheet 5 is formed in a rectangle that is slightly smaller than the holding member 2. The base material of the insulation sheet 5 is made of a highly heat resistant material such as polyimide or cellulose, for example. The insulation sheet 5 is provided with a plurality of void portions 51 which are rectangular holes. The void portions 51 include void portions 51 for the semiconductor switches 41 and void portions 51 for the chip components 42, which are smaller than the semiconductor switches 41. Note that the void portions 51 are not limited to this configuration, and the number, shape, and size of the void portions 51 may be determined as appropriate based on the number of the circuit components 4 that are mounted on the circuit board 1, and the size of the circuit components 4, and the length of the terminals 411 of the circuit components 4, and so on.

A pressure-sensitive adhesive or adhesive layer is provided on both sides of the insulation sheet 5. The adhesive layer is formed of, for example, an epoxy resin adhesive. The pressure-sensitive adhesive layer is formed of, for example, an acrylic pressure-sensitive adhesive or a silicone pressure-sensitive adhesive.

As shown in FIG. 1, the insulation sheet 5 is provided so that the insulation sheet 5 covers one side of the bus bars 3 held by the holding member 2. Since the pressure-sensitive adhesive or adhesive layer is provided on both sides of the insulation sheet 5, the insulation sheet 5 is fixed to the one side of the bus bars 3 by the pressure-sensitive adhesive or adhesive layer. The void portions 51 of the insulation sheet 5 are respectively formed at positions corresponding to the terminals 411 and the electrodes 421 of the circuit components 4 based on the positions at which the circuit components 4 are mounted. Portions of the bus bars 3 are exposed from the void portions 51 of the insulation sheet 5.

A conductive material 6 is applied to the regions of the bus bars 3 exposed from the void portions 51. The conductive material 6 is a solder paste, for example.

The circuit components 4 include semiconductor switches 41 and chip components 42. The semiconductor switches 41 are n-channel FETs having a drain terminal, a source terminal, and a gate terminal, for example. The chip components 42 are small components such as a chip resistor having two electrodes 421, for example. The circuit components 4 such as the semiconductor switches 41 and the chip components 42 are placed on the bus bars 3 on which the terminals 411 and the electrodes 421 of the circuit components 4 are exposed from the void portions 51, and mounted on the circuit board 1. Since the conductive material 6, such as solder paste, is applied to the void portions 51, the terminals 411 and the electrodes 421 of the circuit components 4 are electrically connected to the bus bars 3.

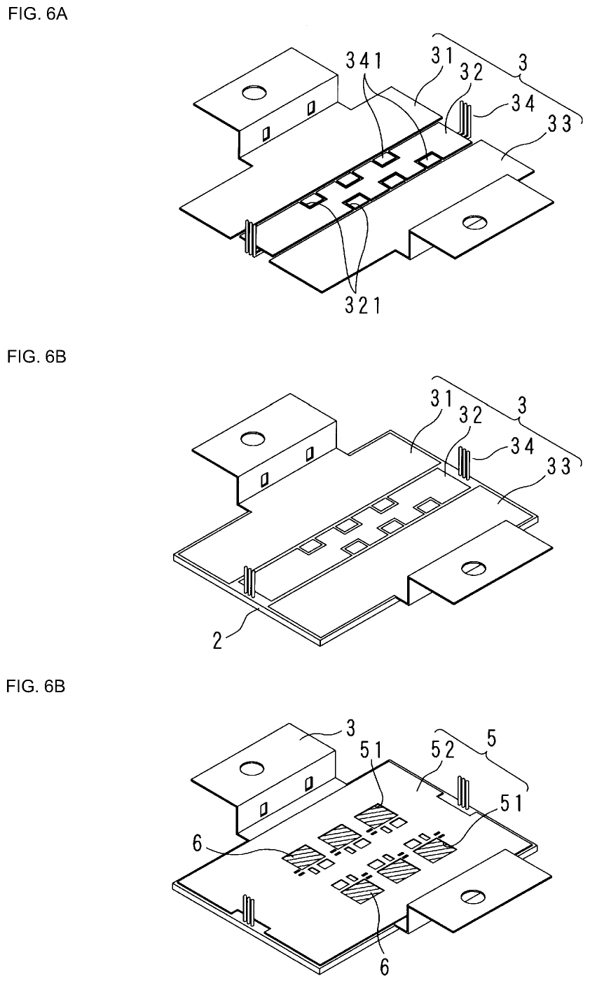

FIG. 5 is a schematic cross-sectional view of the main part of the circuit board. The input bus bar 31 and the connection bus bar 32 are held by the holding member 2 with the placement portions 311 and 331 on which the circuit components 4 are mounted being arranged in parallel with each other. The protruding ridges 23 of the holding member 2 are provided between the placement portion 311 of the input bus bar 31 and the placement portion 331 of the connection bus bar 32 so that the protruding ridges 23 are located between the end faces of the input bus bar 31 and the connection bus bar 32. The thicknesses of the placement portion 311 of the input bus bar 31 and the placement portion 331 of the connection bus bar 32 are set to substantially the same as the height of the protruding ridges 23 (the height for which the protruding ridges protrude from the base portion 21), and one side of the placement portion 311 of the input bus bar 31, one side of the placement portion 331 of the connection bus bar 32, and one end face of the protruding ridges 23 are set substantially flat without a level difference. The insulation sheet 5 is adhered to the one end face of the protruding ridges 23, the one side of the placement portion 311 of the input bus bar 31, and the one side of placement portion 331 of the connection bus bar 32.

The void portions 51 are formed in the insulation sheet 5 so that the void portions 51 correspond to the terminals 411 and the electrodes 421 of the circuit components 4 to be mounted, and the remaining portion located between the two void portions 51 is adhered to the one end face of the protruding ridges 23 of the holding member 2.

The circuit component 4 shown in FIG. 5 is a chip component 42. The chip component 42 includes two electrodes 421, and one electrode 421 is placed at a region of the input bus bar 31 that is exposed from the void portion 51. Another electrode 421 of the chip component 42 is placed at the region of the connection bus bar 32 that is exposed from the void portion 51. A side face (bottom) of the chip component 42 on which the electrodes 421 are provided is in contact with the insulation sheet 5. Since the pressure-sensitive adhesive or adhesive layer is provided on the insulation sheet 5, the chip component 42 is pressure-sensitively adhered or adhered, and fixed by the pressure-sensitive adhesive or adhesive layer of the insulation sheet 5.

The conductive material 6 is applied to the regions of the input bus bar 31 and the connection bus bar 32 that are exposed from the void portions 51. As shown in FIG. 5, the electrodes 421 of the chip component 42 are covered by the conductive material 6 and joined to each other, and the electrodes 421 are electrically connected to the input bus bar 31 and the connection bus bar 32, respectively.

Since the insulation sheet 5 has a certain thickness, the applied conductive material 6 is surrounded by the inner circumferential faces of the void portions 51, and lands formed by the conductive material 6 can be formed. Since the conductive material 6 is surrounded by the inner circumferential faces of the void portions 51, it is possible to suppress the applied conductive material 6 from flowing out from the void portions 51. Since the void portions 51 of the insulation sheet 5 can be formed as appropriate corresponding to the terminals 411 and the electrodes 421 of the circuit components 4 to be mounted on the circuit board 1, even if small components such as the chip components 42 are mounted, it is possible to improve the density of the mounted components, and reduce the size of the circuit board 1.

### Manufacturing Method

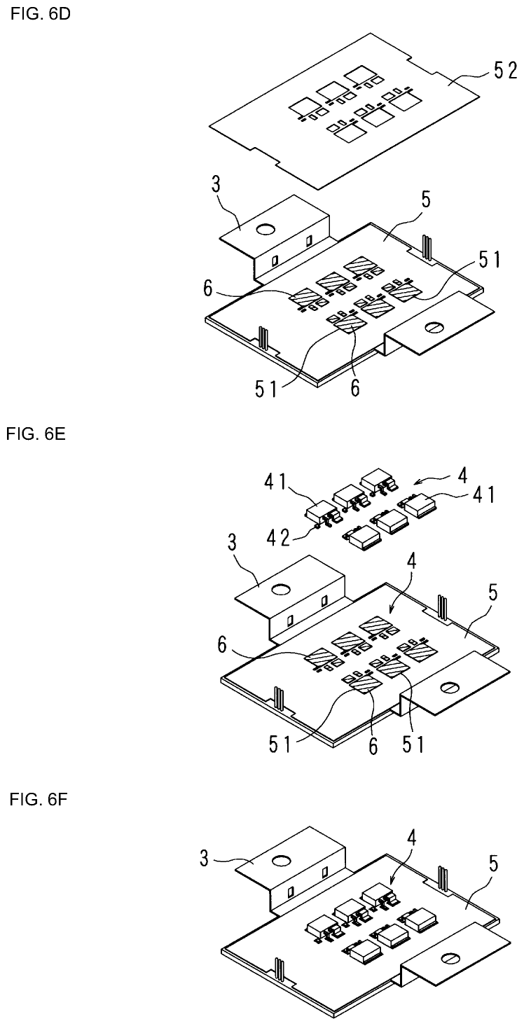

FIGS. 6A to 6F are diagrams illustrating a method for manufacturing the circuit board. Hereinafter, the method for manufacturing the circuit board 1 according to the first embodiment will be illustrated with reference to the FIGS. 6A to 6F.

First, the input bus bar 31, the connection bus bar 32, and the output bus bar 33 are arranged in this order, with their edges facing each other and spaced apart from each other (see. FIG. 6A). Then, the terminal placement portions 341 of the terminal bus bars 34 are aligned with the corresponding cutout portions 321 of the connection bus bar 32 from the other side of the connection bus bar 32.

Next, the input bus bar 31, the connection bus bar 32, the output bus bar 33 and the terminal bus bars 34, arranged as above, are disposed in a resin mold such as an insert molding mold, for example, and a resin such as polyphenylene sulfide resin is poured into the mold. The poured resin flows along the path formed in the mold, and the holding member 2 having the base portion 21, the rectangular plate-like protruding portion 22, and the protruding ridges 23 is formed. The input bus bar 31, the connection bus bar 32, the output bus bar 33 and the terminal bus bars 34 are formed in one piece with the holding member 2 (subjected to insert molding, see FIG. 6B).

Next, the insulation sheet 5 on which the cutout portions 321 are formed is adhered to the one side of the placement portion 311 of the input bus bar 31, the connection bus bar 32, the placement portion 331 of the output bus bar 33, and the terminal placement portions 341 of the terminal bus bars 34 so as to cover them. Since the pressure-sensitive adhesive or adhesive layer is provided on both sides of the insulation sheet 5, the insulation sheet 5 is pressure-sensitively adhered or adhered to the one side of the input bus bar 31 and the like by the pressure-sensitive adhesive or adhesive layer. Since the cutout portions 321 are formed corresponding to the terminals 411 and the electrodes 421 of the circuit components 4 to be mounted, portions of the bus bars 3 on which the terminals 411 and the electrodes 421 of the circuit components 4 are placed are exposed from the cutout portions 321. A silicone-coated protection paper 52 is adhered to one side of the insulation sheet 5 in advance, and the thickness of the insulation sheet 5 including the protection paper 52 is, for example, 140 micromillimeters. Thereafter, the conductive material 6, such as solder paste, is applied to the regions of the bus bars 3 exposed from the void portions 51 of the insulation sheet 5 (see FIG. 6C). This application is performed by, for example, supplying the conductive material 6, such as solder paste, to the protection paper 52 of the insulation sheet 5, and transferring the conductive material 6 from the void portions 51 to the surface of the bus bars 3 with use of a squeegee.

Next, the protection paper 52 is removed from the insulation sheet 5 (see FIG. 6D). By removing the protection paper 52 from the insulation sheet 5, the pressure-sensitive adhesive or adhesive layer provided on the one side of the insulation sheet 5 is exposed.

Next, the semiconductor switches 41 and the chip components 42 serving as the circuit components 4 are aligned with the cutout portions 321 corresponding to the terminals 411 and the electrodes 421 thereof (see FIG. 6E). Thereafter, the terminals 411 and the electrodes 421 of the semiconductor switches 41 and the chip components 42 are placed on the bus bars 3 exposed from the cutout portions 321 (see FIG. 6F). The bottom of the packages of the semiconductor switches 41 and the chip components 42 are in contact with the insulation sheet 5, and the semiconductor switches 41 and the chip components 42 are fixed to the bus bars 3 by the pressure-sensitive adhesive or adhesive layer provided on the one side of the insulation sheet 5. The circuit board 1 on which the semiconductor switches 41 and the chip components 42 are fixed is introduced into a reflow furnace, and the conductive material 6, such as solder paste, is melted so that the terminals 411 and the electrodes 421 are joined and electrically connected to the bus bars 3.

In this manner, by using the insulation sheet 5 in which the void portions 51 are provided, it is possible to suppress the melted solder from leaking and spreading out from the void portions 51 to the surrounding areas, and appropriate solder fillets can be formed in a state where a certain amount of solder is held. By fixing the small components such as the chip components 42 by the pressure-sensitive adhesive or adhesive layer provided on the surface of the insulation sheet 5, it is possible to suppress a phenomenon on which the chip components 42 rise up (Manhattan phenomenon) when the circuit board 1 is introduced into the reflow furnace, and the rate of yield when manufacturing of the circuit board 1 can be improved.

The disclosed embodiments are illustrative examples in all aspects and should not be considered as restrictive. The scope of the present invention is defined not by the above description but by the claims, and is intended to encompass all modifications within the meaning and scope that are equivalent to the claims

1. A circuit board comprising:
a plurality of conductive plates held by a holding member;
an insulation sheet provided on one side of the conductive plates; and
a circuit component that is placed on at least one of the conductive plates and that has a terminal,
wherein a void portion is formed in the insulation sheet, and a conductive material for electrically connecting the conductive plate and the terminal to each other is applied to a region that is exposed from the void portion on the one side of the conductive plate,
the insulation sheet is provided so as to cover one side of the plurality of conductive plates, and fixed to the one side of the plurality of conductive plates,
the insulation sheet has a pressure-sensitive adhesive or adhesive layer on both sides thereof, and
the circuit component is fixed to the conductive plate with the pressure-sensitive adhesive or adhesive layer.

2. (canceled)

3. The circuit board according to claim 1, wherein the pressure-sensitive adhesive layer is formed of an acrylic pressure-sensitive adhesive.

4. The circuit board according to claim 1, wherein the base material of the insulation sheet is made of polyimide or cellulose.

5. The circuit board according to claim 1 wherein the holding member is made of polyphenylene sulfide resin.

6. The circuit board according to claim 1, wherein the circuit component includes a semiconductor switch, and a chip component that is smaller than the semiconductor switch, and
the void portions are respectively formed corresponding to the terminals of the semiconductor switch and the chip component.

7. A method for manufacturing a circuit board comprising steps of:
arranging a plurality of conductive plates at a predetermined position in a mold and forming a holding member by pouring resin into the mold, while forming the plurality of conductive plates and the holding member in one piece;
providing an insulation sheet, on which a void portion is formed and that has a pressure-sensitive adhesive or adhesive layer on both sides and a protection paper adhered to one side thereof so as to cover one side of the plurality of conductive plates, with a side on which the protection paper is not adhered facing the plurality of conductive plates, and fixing the insulation sheet to the one side of the plurality of conductive plates;
applying a conductive material to a region of the conductive plate where the void portion is located;
removing the protection paper from the insulation sheet, and
aligning a terminal of a circuit component with the void portion, placing the terminal on the conductive plate to which the conductive material is applied, and adhering or gluing the circuit component to the insulation sheet to fix the circuit component to the conductive plate.

8. The circuit board according to claim 3, wherein the base material of the insulation sheet is made of polyimide or cellulose.

9. The circuit board according to claim 3, wherein the holding member is made of polyphenylene sulfide resin.

9. The circuit board according to claim 4, wherein the holding member is made of polyphenylene sulfide resin.

10. The circuit board according to claim 3, wherein the circuit component includes a semiconductor switch, and a chip component that is smaller than the semiconductor switch, and
the void portions are respectively formed corresponding to the terminals of the semiconductor switch and the chip component.

11. The circuit board according to claim 5, wherein the circuit component includes a semiconductor switch, and a chip component that is smaller than the semiconductor switch, and
the void portions are respectively formed corresponding to the terminals of the semiconductor switch and the chip component.
